(19) United States
(12) Patent Application Publication
(10) Pub. No.: US 2015/0243804 A1
(43) Pub. Date: Aug. 27, 2015

(54) PHOTOVOLTAIC SOLAR CELL AND METHOD FOR PRODUCING A PHOTOVOLTAIC SOLAR CELL

(71) Applicant: Fraunhofer-Gesellschaft zur Förderung der Angewandten Forschung e.V., München (DE)

(72) Inventors: Benjamin Thaidigsmann, Freiburg (DE); Elmar Lohmuller, Freiburg (DE); Florian Clement, Freiburg (DE); Andreas Wolf, Freiburg (DE); Daniel Biro, Freiburg (DE); Ralf Preu, Freiburg (DE)

(73) Assignee: FRAUNHOFER-GESELLSCHAFT ZUR FÖRDERUNG DER ANGEWANDTEN FORSCHUNG E.V., Munchen (DE)

(21) Appl. No.: 14/430,025

(22) PCT Filed: Sep. 12, 2013
(86) PCT No.: PCT/EP2013/068940

§ 371 Date: Mar. 20, 2015

(30) Foreign Application Priority Data
Sep. 21, 2012 (DE) 10 2012 217 078.2

(51) Int. Cl. H01L 31/0224; H01L 31/02; H01L 31/0236

(52) U.S. Cl. CPC H01L 31/02245; H01L 31/02363; H01L 31/02008

(57) ABSTRACT

A photovoltaic solar cell with a front face designed for coupling light, including at least one cutout (4) extending from the front face to the rear face in the semiconductor substrate (1) of a base doping type, at least one metal feedthrough structure (10), wherein the feedthrough structure (10) is guided in the cutout (4) from the front face to the rear face of the semiconductor substrate and is connected in an electrically conductive manner to the metal front face contact structure (9), which is connected in an electrically conductive manner to an emitter region (2) of the opposite doping to the base doping type, formed on the front face, and at least one rear face contact structure (7), which is connected to the feedthrough structure (10) in an electrically conductive manner and is arranged on the electrically insulating insulation layer (6) on the rear face and covers the isolation layer at least in the regions surrounding the recess (4), and therefore the rear face contact structure (7) is electrically isolated by the insulation layer (6) against the semiconductor substrate (1) lying beneath the insulation layer (6). It is essential that the feedthrough structure (10) directly adjoins a base region of the base doping type on the walls of the recess (4) in the semiconductor substrate (1). The invention further relates to a method for producing a photovoltaic solar cell.

### BACKGROUND

The invention relates to a photovoltaic solar cell and to a method for producing a photovoltaic solar cell.

Photovoltaic solar cells typically are formed of a semiconductor structure having a base region and an emitter region, wherein the semiconductor structure is typically substantially formed by a semiconductor substrate, such as a silicon substrate, for example. Light is coupled into the semiconductor structure typically via the front side of the solar cell, such that generation of electron-hole pairs takes place after absorption of the coupled-in light in the solar cell. A pn junction forms between base and emitter region, the generated charge carrier pairs being separated at said junction. Furthermore, a solar cell comprises a metallic emitter contact and also a metallic base contact, which are respectively electrically conductively connected to the emitter and to the base. Via these metallic contacts, the charge carriers separated at the pn junction can be conducted away and thus fed to an external electric circuit or an adjacent solar cell in the case of module interconnection.

Various solar cell structures are known, wherein the present invention relates to those solar cell structures in which both electrical contacts of the solar cell are arranged on the rear side, wherein electrical contact can be made with the base of the solar cell via a metallic base contact structure arranged on the rear side, and electrical contact can be made with the emitter of the solar cell via a metallic rear-side contact structure arranged on the rear side. This is in contrast to standard solar cells, in which typically the metallic emitter contact is situated on the front side and the metallic base contact is situated on the rear side of the solar cell.

In this case, the invention relates to a specific configuration of a solar cell with which contact can be made on the rear side, the metal wrap-through solar cell (MWT solar cell). This solar cell, known from EP 985233 and van Kerschaver et al. “A novel silicon solar cell structure with both external polarity contacts on the back surface” Proceedings of the 2nd World Conference on Photovoltaic Energy Conversion, Vienna, Austria, 1998, indeed has a metallic front-side contact structure arranged at the front side of the solar cell designed for coupling in light, said front-side contact structure being electrically conductively connected to the emitter region. However, the solar cell furthermore has a multiplicity of cutouts extending from the front side to the rear side in the semiconductor substrate, with metallic feedthrough structures penetrating through said cutouts and said cutouts being electrically conductively connected on the rear side to one or more metallic rear-side contact structures, such that electrical contact can be made with the emitter region on the rear side via the rear-side contact structure, the feedthrough structure and the front-side contact structure.

The MWT structure has the advantage that the charge carriers are collected from the emitter at the front side via the front-side contact structure and, consequently, no ohmic losses arise as a result of possible charge carrier transport within the semiconductor substrate from the front side to the rear side with regard to the emitter region. Furthermore, the capability of making contact both with the base region and with the emitter region on the rear side results in a simpler interconnection of the MWT solar cells in the module compared with standard solar cells.

What is disadvantageous about the MWT structure is that, compared with standard solar cells, it is necessary to produce additional structures such as, for example, the cutouts and the metallic feedthrough structures through the cutouts, thus resulting in a higher complexity and hence higher costs compared with the production of standard solar cells. Moreover, in particular in the case of inaccurate processing on the walls of the cutouts and also in the region in which the rear-side contact structures cover the rear side of the solar cell, there are risks concerning the formation of additional loss mechanisms; in particular, short-circuit currents can occur if the rear-side contact structure faultily penetrates into the base region of the semiconductor substrate (so-called “spiking” or “shunting”), as a result of which the efficiency of the solar cell is considerably reduced.

For this reason, EP 0 985 233 proposes leading the emitter through the cutouts and, at the rear side, at least beyond the regions covered by the rear-side contact structure, such that the rear-side contact structure, serving for making contact with the emitter externally, covers no region of the semiconductor substrate having the base doping.

However, this requires complex processing and a plurality of cost-intensive masking steps.

Therefore, DE 10 2010 026 960 A1 discloses forming an MWT structure having emitter regions on the front side—facing the light incidence—and the walls of the cutouts, but not on the rear side.

An MWT structure disclosed in WO 2012/026812 is simplified more extensively with regard to the structure design, in which MWT structure no emitter is formed on the walls of the cutouts and the metallic feedthrough structure directly adjoins the semiconductor substrate, i.e. is not insulated from the cutouts by an electrically insulating intermediate layer in said cutouts. In accordance with the teaching of said disclosure, therefore, the through-metallization is to be formed with a conductivity decreasing in a horizontal direction proceeding from the center of the through-metallization toward the edges.

Due to the increasing price pressure in the production of photovoltaic solar cells, there is great demand for cost-effective and at the same time reliable production methods and suchlike solar cell structures.

### SUMMARY

Therefore, the invention is based on the object of providing an MWT solar cell and a method for producing an MWT solar cell which is distinguished by a reliable and robust and at the same time cost-effective construction.

This object is achieved by a photovoltaic solar cell and by a method for producing a photovoltaic solar cell according to the invention. Advantageous configurations of the photovoltaic solar cell according to the invention are described below. Advantageous configurations of the method according to the invention are also described below. The wording of all the claims is hereby explicitly incorporated by reference in the description. The photovoltaic solar cell according to the invention is preferably formed by the method according to the invention or a preferred embodiment thereof. The method according to the invention is preferably designed for forming a solar cell according to the invention for a preferred embodiment thereof.

The present invention is based on the insight that the previous optimizations of MWT structures were surprisingly based on an erroneous weighting of the loss mechanisms, such that an emitter on the walls of the cutouts and/or an electrically insulating layer on the walls of the cutouts and/or at least one feedthrough structure having a conductivity that decreases toward the walls of the cutout are/is absolutely necessary according to the previously known teaching in order to form an efficient and reliable MWT solar cell.

Surprisingly, however, the MWT structure apparently simplified to the greatest extent and disclosed in FIG. 4 and associated description in WO 2012/026812 cited above has a disadvantage that has not been sufficiently appreciated hitherto: it is true that in normal operation, i.e. under optimum test conditions, such solar cells exhibit a good efficiency and in particular only low shunts, i.e. a high assigned parallel resistance in the global evaluation. However, under reverse loading, such as can occur for example under real conditions and partial shading of a portion of solar cells in a module, such solar cells have a considerably lower breakdown voltage compared with other MWT structures, that is to say that a so-called reverse breakdown occurs at a considerably lower voltage. Due to the considerable local evolution of heat that occurs with such a breakdown, this constitutes a considerable risk of such solar cell structures being susceptible to damage to the module through to the development of fire in the case of partial shading. For a robust module design, therefore, in the case of such solar cells, additional bypass diodes would need to be provided, which in turn increase costs and nullify the cost advantage due to the reduced solar cell structure.

Furthermore, it has been possible to show, however, that in particular the large-area metallization of the rear-side contact structure is crucial for the abovementioned behavior in the case of partial shading, and that the comparatively slight area at which the feedthrough structure adjoins the walls of the cutout does not, however, constitute a considerable risk for a reduced breakdown voltage under reverse loading.

By implementing these surprising insights, it has been possible to develop a novel MWT solar cell structure and a method for producing same which firstly enables a further cost saving in comparison with the structure disclosed in DE 10 2010 026 960 A1 and nevertheless avoids the disadvantages of a solar cell structure in particular in accordance with FIG. 4 of WO 2012/026812:

The photovoltaic solar cell according to the invention has a front side designed for coupling in light and comprises a semiconductor substrate of a base doping type, and at least one emitter region of an emitter doping type formed at the front side, said emitter doping type being opposite to the base doping type. In this case, doping types are the n-type doping and the p-type doping opposite thereto.

The solar cell furthermore comprises at least one metallic front-side contact structure which is formed on the front side for the purpose of collecting current and which is electrically conductively connected to the emitter region, at least one metallic base contact structure which is arranged at the rear side of the solar cell and is electrically conductively connected to the semiconductor substrate in a region of the base doping type, at least one cutout extending from the front side to the rear side in the semiconductor substrate and at least one feedthrough structure, wherein the feedthrough structure is guided in the cutout from the front side to the rear side of the semiconductor substrate and is electrically conductively connected to the front-side contact structure, and at least one metallic rear-side contact structure which is arranged at the rear side and is electrically conductively connected to the feedthrough structure.

An electrically insulating insulation layer is arranged on the rear side of the semiconductor substrate, indirectly or preferably directly, and covers the rear side at least in the regions surrounding the cutout, preferably completely. The rear-side contact structure is arranged on the insulation layer indirectly or preferably directly, such that the rear-side contact structure is electrically insulated by the insulation layer from the semiconductor substrate lying below the insulation layer.

With regard to this basic construction, the solar cell according to the invention thus corresponds to the proven MWT structure described for example in DE 10 2010 026 960 A1.

What is essential is that, in the case of the solar cell according to the invention, in the semiconductor substrate on the walls of the cutout, the feedthrough structure directly adjoins a base region of the base doping type.

The solar cell structure according to the invention is thus based on the surprising insights that, firstly, a reliable electrical insulation between rear-side contact structure and base region of the semiconductor substrate is essential at the rear side of the solar cell with regard to the reliability of the solar cell in particular in the case of partial shading, that cost advantages are afforded by forming no emitter at the rear side, and that, due to the comparatively small area portions, the fact of the feedthrough structure directly adjoining the base region on the walls of the cutout does not lead or leads only slightly to an impairment of the efficiency and the behavior in the case of partial shading of the solar cell. As a result, a reduction of costs is achieved in the production of the MWT solar cell according to the invention in comparison with previously known MWT solar cells and, nevertheless, there is no or only a negligible reduction of efficiency and impairment of the behavior in the case of reverse loading, in particular no increase in the current intensity in the case of reverse loading. Furthermore, the feedthrough structure can be formed homogeneously, in particular with homogeneous conductivity, and in particular a conductivity that decreases toward the walls of the cutouts is not necessary.

The method according to the invention for producing a photovoltaic solar cell having a front side designed for coupling in light comprises the following method steps:

A method step A involves producing a plurality of cutouts in a semiconductor substrate of a base doping type.

A method step B involves producing one or more emitter regions of an emitter doping type at least at the front side of the semiconductor substrate, wherein the emitter doping type is opposite to the base doping type.

A method step C involves applying an electrically insulating insulation layer on the rear side of the semiconductor substrate. A method step D involves producing at least one metallic base contact structure at the rear side of the solar cell, which is formed in an electrically conductive manner with the semiconductor substrate in a base doping region. Furthermore, method step D involves producing at least one metallic front-side contact structure at the front side of the solar cell, which is formed in an electrically conductive manner with the emitter region at the front side of the semiconductor substrate, and producing at least one rear-side contact structure at the rear side of the solar cell, which is formed in a manner electrically conductively connected to the feedthrough contact structure.

In method step C the insulation layer is applied in a manner covering the rear side of the semiconductor substrate indirectly or preferably directly.

Furthermore, in method step D the rear-side contact structure is applied to the insulation layer indirectly or preferably directly, such that the rear-side contact structure extends over a region of the semiconductor substrate having base doping and, in these regions, due to the intervening insulation layer, an electrical insulation is formed between rear-side contact structure and semiconductor substrate. In method step D, the base contact structure is applied to the insulation layer indirectly or preferably directly, in such a way that the base contact structure penetrates through the insulation layer at least in regions, such that an electrically conductive connection is produced between base contact structure and semiconductor substrate.

With regard to these method steps, the method according to the invention corresponds for example to the method described in DE 10 2010 02 960 A1. However, this does not concern the order of the method steps and/or the addition of further method steps:

What is essential to the method according to the invention is that in the semiconductor substrate on the walls of the cutout the feedthrough structure (10) away from the front-side emitter region is formed in a manner directly adjoining a base region of the base doping type.

As a result, in a cost-effective manner, an MWT solar cell is produced in which the metallic rear-side contact structure at the rear side of the semiconductor substrate is electrically insulated from the semiconductor substrate at least by the insulation layer, but no emitter is explicitly formed on the walls of the cutouts and, moreover, no specially formed electrical insulation layer is formed between the feedthrough structure and the walls of the cutouts.

This affords the advantages already mentioned for the photovoltaic solar cell according to the invention. In particular, the method according to the invention is more cost-effective than previously known methods, in particular the method described in DE 10 2010 026 960 A1. This is because in the previously known method, after the production of the cutouts, a further surface treatment of the semiconductor substrate in the cutouts is essential since otherwise the emitter formed on the walls of the cutout is formed in a disadvantageous manner (with a high jot proportion in the assigned two-diode model, i.e. a leakage current in the space charge zone). Such a cost-intensive additional method step for the subsequent treatment of the surface of the semiconductor substrate in the cutouts can be dispensed with in the case of the methods according to the invention since there is no significant emitter covering present on the walls of the cutout. Consequently, possible surface damage to the walls of the cutout plays only a minor part.

In a preferred manner, method step A is performed after method step B and preferably also after method step C. For this ensures that in method step B no emitter can be formed on the walls of the cutout since the cutout are only produced afterward, and/or that the insulation layer is opened at the cutouts in a simple manner and no insulation layer is formed in the cutouts since the cutouts are produced only after the formation of the insulation layer.

In a further preferred embodiment, method step A is performed before method step B and preferably also before method step C. As a result, in method step B at least slightly an emitter is also formed on the walls of the cutouts produced in method step A, if appropriate also on the rear side of the solar cell. Therefore, in this preferred embodiment, in a method step X after method step B the emitter is removed again on the walls of the cutouts and, if appropriate, also on the rear side of the solar cell. This can preferably be carried out by means of a wet-chemical or plasma-based emitter back-etch. Suitable methods are known from INDUSTRIAL REALIZATION OF DRY PLASMA ETCHING FOR PSG REMOVAL AND REAR SIDE EMITTER ETCHING, EU-PVSEC, Rentsch, 2007, and from SINGLE SIDE ETCHING—KEY TECHNOLOGY FOR INDUSTRIAL HIGH EFFICIENCY PROCESSING, EU-PVSEC, Rentsch, 2008. In particular, wet-chemical processes can be used in combination with etch stop masks.

In a further preferred embodiment, method step A is performed before method step B and preferably also before method step C. Furthermore, in a method step Y1 after method step A and before method step B, a diffusion barrier layer is applied to the walls of the cutout, in particular also to the rear side of the solar cell, which in method step B thus prevents the formation of an emitter on the walls of the cutout and, if appropriate, on the rear side of the solar cell. Said diffusion barrier layer is removed again in a method step Y2 after method step B. Method step Y1 is preferably performed by producing a diffusion barrier layer by thermal oxidation, if appropriate with the interposition of further steps, by physical coating methods such as cathode sputtering or chemical deposition methods, in particular PECVD. Suitable materials for diffusion barrier layers are, in particular, SiOx, SiNx, AlOx, SiCx, TiNx. Furthermore, spraying and printing processes can be used for producing suitable diffusion barrier layers. Method step Y2 is preferably performed by the diffusion barrier layer being removed again wet-chemically or by means of plasma-based etching methods. The diffusion barrier layer is preferably removed together with the dopant source, preferably by means of hydrofluoric acid.

Preferably, in the case of the photovoltaic solar cell according to the invention, no emitter is formed on the rear side of the solar cell. This obviates complex method steps, in particular maskings or selective printing of doping pastes at the rear side.

Preferably, the metallic rear-side contact structure covers at least 0.1% of the rear-side insulation layer, more preferably a maximum of 5% of the rear-side insulation layer. A coverage in the range of 0.5% to 3%, in particular 0.5% to 1.5%, of the rear-side insulation layer is preferred. The aforementioned percentages relate to the area coverage.

Preferably, the solar cell according to the invention has a multiplicity of cutouts with feedthrough structures, preferably between 10 and 70 per solar cell.

Preferably, the feedthrough structures are formed by means of a non-contacting metal paste in the method according to the invention. Such non-contacting metal pastes are known per se and described for example in Michael Neidert et al., “DEVELOPMENT OF VIA PASTES FOR HIGH EFFICIENCY MWT CELLS WITH A LOW SHUNTING BEHAVIOUR”, 24th European Photovoltaic Solar Energy Conference, Sep. 21-25, 2009, Hamburg, Germany. Such metal pastes have the advantage of forming, with respect to an adjoining semiconductor layer, no contact or only contact provided with a high contact resistance. The risk of a short circuit (a shunt) on the walls of the cutouts is additionally reduced in this way.

Furthermore, the solar cell structure according to the invention and the method according to the invention afford a higher flexibility with regard to the formation of the through-metallization structures:

It likewise lies within the scope of the invention to form the feedthrough structures by means of metal pins or by means of conductive adhesive in method step D. In particular, it lies within the scope of the invention to finish the solar cells per se and to form the feedthrough structures only during the integration of a plurality of solar cells in the module, in particular by means of metal pins which can be provided for example on an already interconnected carrier for receiving a plurality of MWT solar cells. What is essential is that the feedthrough structures electrically conductively connect the front-side contact structure to the rear-side contact structure, preferably with an electrical conduction resistance from the front side to the rear side of less than 20 mohms, preferably less than 10 mohms, more preferably less than 5 mohms. The feedthrough structures are preferably formed in a metal-containing fashion, in particular in a metallic fashion.

Preferably, the feedthrough structures are formed homogeneously or at least substantially homogeneously with regard to the conductivity. Particularly in comparison with the feedthrough structure disclosed in WO 2012/026812, simpler and more cost-effective production of a feedthrough structure is afforded, without the previously described profile of the conductivity in a horizontal direction.

In the case of the method according to the invention, the feedthrough structure is preferably formed in a manner directly adjoining one or a plurality of base regions of the base doping type.

Preferably, in the case of the method according to the invention, no emitter region extending parallel to the rear side is formed in a manner adjoining the cutout at the rear side of the semiconductor substrate.

Both the preferred embodiments mentioned above lead in each case to a reduction of the costs of the production method.

Furthermore, it is advantageous to implement the cutouts by means of a laser; in this case, in a cost-effective manner, it is possible to have recourse to devices for solar cell production that are known per se. In particular, the use of a laser guided in a liquid jet is advantageous since here, firstly, an exact, approximately cylindrical cutout can be formed and, furthermore, a surface at the cutouts with comparatively little damage and thus a low surface recombination rate can be created by means of the choice of additives in the liquid.

Preferably, the emitter is formed by means of back-to-back diffusion in method step B. In this case, the semiconductor substrates are introduced into the diffusion area with the rear sides bearing against one another, such that—without the need for additional masking layers—the emitter diffusion takes place only on the respective front side of the semiconductor substrate.

Preferably, method step B is carried out after method step C. This affords the advantage that the insulation layer applied in method step C on the rear side of the semiconductor substrate acts as a diffusion barrier in the indirectly or directly subsequent method step B, such that the formation of the emitter only on the front side of the semiconductor substrate is obtained in a cost-effective manner as a result of this multiple function of the insulation layer.

It is known to provide a texturing in order to increase the coupling-in of light and/or the internal reflection and thus the efficiency of the solar cell at the front side facing the incidence of light. Preferably, therefore, a texturing of at least the front side of the semiconductor substrate is carried out in a method step T. The texturing can be carried out in a manner known per se, depending on the semiconductor substrate, for example by the formation of so-called “random pyramids” or other optical textures known per se for increasing the coupling-in of light and/or the internal reflection. It is particularly advantageous for method step T to be performed after method step C. As a result, the insulation layer can additionally serve as a masking layer in such a way that a texture is formed only on the front side of the semiconductor substrate. Here, too, a multiple function of the insulation layer is thus implemented, such that method steps can be saved in a cost-effective manner.

The solar cell according to the invention and the method according to the invention furthermore afford a considerable advantage with regard to the flexibility in the choice of the solar cell structure to be formed:

Advantageously, therefore, in the case of the method according to the invention, firstly a multiplicity of so-called precursors are provided by virtue of method steps B and C and preferably also method step T being performed in each case on a multiplicity of semiconductor substrates. This affords the advantage that said precursors do not yet have any cutouts and it is therefore not yet fixed whether a conventional solar cell structure without cutouts or an MWT solar cell structure according to the present invention is formed by means of said precursors.

Consequently, prefabricated precursors can be provided and it is then optionally possible, depending on the job order situation, to produce conventional solar cells contacted on both sides without the formation of cutouts or, by means of carrying out method steps A and D, MWT solar cells according to the invention.

The electrically insulating insulation layer at the rear side of the solar cell according to the invention preferably covers the rear side substantially over the whole area, is embodied as a passivation layer and thus fulfills a plurality of functions: firstly, the insulation layer serves for electrical insulation between metallic rear-side contact structure and semiconductor substrate. Secondly, it preferably likewise serves for electrically insulating the metallic base contact structure from the semiconductor substrate, excluding a plurality of area regions which are small in comparison with the total rear-side areas of the solar cell and at which the base contact structure makes contact with the semiconductor substrate and is electrically conductively connected thereto. Furthermore, the passivation layer advantageously serves for improving the internal reflection of the solar cell and/or the rear-side passivation. In order to fulfill the tasks mentioned above, the dielectric passivation layer can be formed as a silicon oxide layer, in particular silicon dioxide layer. It likewise lies within the scope of the invention to embody the dielectric layer as a silicon nitride layer, aluminum oxide layer or silicon carbide layer. It likewise lies within the scope of the invention to use a system comprising a plurality of different layers (stack system) as insulation layer, wherein the different layers preferably fulfill different functions. Such a layer system can for example a passivating layer for reducing the surface recombination rate (in particular one or more of the following layers SiOₓ, AlₓO_{y}, SiNₓ, SiₓN_{y}O_{z}, SiCₓ), an electrically insulating layer and possibly an additional protective layer (for example SiNₓ), which protective layer protects the substrate and the underlying layers in high-temperature steps such as contact firing, for example, against the material used as rear-side contact (typically aluminum for making contact with p-doped regions).

The individual method steps in the method according to the invention can preferably be performed identically or analogously to DE 10 2010 026 960 A1, in particular with regard to the method parameters. The disclosure of DE 10 2010 026 960 A1 is explicitly incorporated by reference in this description.

In particular, with regard to the formation of the insulation layer, reference is made to paragraphs [0037] and [0040]. With regard to the formation of the contact structures, reference is made in particular to paragraphs [0038] and [0039] of DE 10 2010 026 960 A1.

In one preferred embodiment of the method according to the invention, before method step B, if appropriate with interposition of further method steps, the rear side of the semiconductor substrate is leveled. The semiconductor substrates typically used, in particular monocrystalline silicon wafers, multicrystalline silicon wafers or microcrystalline silicon wafers, typically have unevennesses which can lead to non-uniform coverage and losses of efficiency resulting therefrom. Leveling avoids such losses of efficiency. The leveling is preferably effected by removing a semiconductor layer at one side, at the rear side, of the semiconductor substrate. In particular, it is advantageous to achieve the removal at one side by wet-chemical etching, by laser ablation or by plasma etching.

The insulation layer can be applied by means of a method known per se, in particular plasma enhanced chemical vapor deposition (PECVD), tube furnace processes, atmospheric pressure chemical vapor deposition (APCVD) or cathode sputtering has the advantage that it is not necessary to remove the silicon dioxide layer at undesired regions such as, for example, the front side of the semiconductor substrate. It is likewise advantageous to use diffusion barriers which are applied by pressure, spraying or a spin-on process, since methods that can be industrially implemented cost-effectively are available for this purpose.

By using the electrical insulation layer as a diffusion barrier when producing the emitter at the front side of the semiconductor substrate and/or by means of carrying out a back-to-back diffusion in which a plurality of semiconductor substrates with their rear side bearing against one another are exposed to an emitter diffusion from the gas phase, it is possible to produce the emitter regions of the solar cell according to the invention in a simple manner. Preferably, in method step B, the emitter region or emitter regions at the front side of the semiconductor substrate is or are produced in a manner comprising one of the following method steps: producing the emitter regions by means of diffusion after deposition of a dopant source on the front side of the semiconductor substrate enables the use of cost-effective process methods, in particular APCVD, PECVD, spraying, printing, saddling and deposition in a dipping bath. Carrying out the diffusion in an inline furnace is particularly advantageous.

Furthermore, it lies within the scope of the invention to produce a heterostructure, in which the emitter is deposited by way of a layer. Likewise, the emitter can also be produced by means of ion implantation.

The cutouts in which the feedthrough structure is formed in further method steps are preferably produced by laser ablation. The advantage when using laser methods is that it is possible to have recourse to known process parameters and the method can be integrated cost-effectively in industrial production lines.

The metallic structures for making contact with the emitter, front-side contact structure, feedthrough contact structure and rear-side contact structure, were designated above by the three terms mentioned in order to identify the spatial arrangement. It lies within the scope of the invention for these structures to be embodied in a multipartite fashion; it likewise lies within the scope of the invention to form only one integral metallization structure comprising front-side contact structure, feedthrough structure and rear-side contact structure.

In one preferred embodiment of the method according to the invention, front-side contact structure, rear-side contact structure and feedthrough contact structure are formed by means of screen printing. This affords the advantage that these processes can be used industrially in an inline method and, in particular, the use of screen printing for producing metallic structures is already known and, consequently, it is possible to have recourse to previously known process parameters. In this case, screen printing paste containing metal particles is used. In this case, preferably by means of screen printing, a metal-containing paste is applied to the rear side of the semiconductor substrate, if appropriate to further intermediate layers, in such a way that the paste penetrates through the cutouts.

Typically, in the case of the solar cell according to the invention, the emitter has the n doping type and the base has the p doping type. It likewise lies within the scope of the invention to form emitter and base with doping types interchanged relative thereto.

The semiconductor substrate is preferably formed as a silicon substrate, in particular as a monocrystalline or with further preference multicrystalline silicon wafer. In particular, the use of a silicon wafer having a base resistance in the range of 0.1 ohm cm to 10 ohms cm is implemented.

As already explained above, one essential aspect of the present invention is that an emitter is not explicitly formed at the rear side of the semiconductor substrate and on the walls of the cutouts. Depending on the chosen sequence and the arrangement of the individual method steps, however, it likewise lies within the scope of the invention for the emitter to penetrate somewhat into the cutouts, that is to say that, proceeding from the front side of the semiconductor substrate, the emitter extends on the walls of the cutouts. It is essential, however, that the emitter is not led as far as the rear side of the semiconductor substrate, such that, at least in that region of the cutout which faces the rear side, no emitter is formed on the walls of the cutouts. Preferably, the emitter formation is restricted to the front side of the semiconductor substrate and thus a few μm of the walls of the cutout on the front side of the semiconductor substrate.

On the front side of the semiconductor substrate, the metallic front-side contact structure is preferably formed in a manner known per se, in particular by means of comb-like or double-comb-like metallic contacting fingers which make contact with the emitter and thus carry away the current, wherein the aforementioned contacting fingers are electrically conductively connected to the respective feedthrough structures, such that the current is conducted to a rear-side external contact in this way.

In order to ensure sufficient penetration of the cutouts with screen printing paste, in the method according to the invention after the screen printing paste has been applied on the front side, a pressure difference is produced between front and rear sides of the semiconductor substrate, in such a way that the paste is forced into the cutouts due to the pressure difference. In this preferred embodiment, therefore, due to the pressure difference, the paste is “sucked” from the rear side through the cutouts, with the result that the production of the feedthrough structures is ensured in a simple manner.

When forming the rear-side contact structure by means of screen printing it is particularly advantageous to use pastes which do not penetrate through the insulation layer during the formation of the contact structures, in particular silver-containing pastes, preferably without additives which attack the insulation layer on the rear side, in particular without or at least with only a small proportion of glass frit. It is thus possible to further reduce the risk of contact formation and hence of a short circuit between semiconductor substrate of the base doping type and rear-side contact.

Further preferred embodiments of the method according to the invention comprise forming front-side contact structure and/or rear-side contact structure and/or feedthrough contact structure by electrodeposition, dispensing, vapor deposition, cathode sputtering or printing methods such as, for example, inkjet or aerosol.

On the rear side of the solar cell according to the invention, the metallic rear-side contact structure and the metallic base contact structure are spaced apart from one another in order to avoid a short circuit. The distance between these two contact structures is preferably at least 100 μm. These contact structures can be formed in a manner known per se and in a form known per se as in the case of previously known MWT solar cells. The aforementioned distance between the contact structures is preferably chosen in such a way that process fluctuations can be afforded tolerance and losses as a result of the transport of charge carriers in the base as far as the closest possible electrically conductive connection are simultaneously minimized. The contact structures preferably have regions (so-called pads) which are provided with a specific surface constitution and/or material composition in order to simplify the electrical connection for an external interconnection.

Further preferred embodiments of the method according to the invention are described below:

After the semiconductor substrate has been provided, sawing damage that is typically present in the case of a semiconductor substrate is preferably removed.

The front side of the semiconductor substrate is then preferably textured, preferably by means of wet-chemical processes or plasma processes (method step T).

The rear side of the semiconductor substrate is then preferably leveled, in particular by means of wet-chemical processes or plasma processes on one side.

Cleaning can then preferably be carried out in order to remove contaminants.

This is then preferably followed by the production of an emitter region on the front side of the semiconductor substrate (method step B) and the production of the insulation layer, in particular a dielectric layer, on the rear side of the semiconductor substrate (method step C). For this purpose, diverse process sequences can be used in a manner known per se. What is essential is that the insulation layer at the rear side has an electrically insulating effect.

An antireflection layer having one or a plurality of plies can subsequently be applied on the front side, for example by means of PECVD or by means of sputtering. It likewise lies within the scope of the invention to apply such an antireflection layer before method step B and additionally to provide the antireflection layer with a dopant source in order to form the emitter.

This is then preferably followed by the formation of the cutouts (method step A), of the feedthrough structures, of the metallic base contact structure, of the metallic front-side contact structure and of the metallic rear-side contact structure (method step D). For this purpose, for example, the cutouts can be formed by means of a laser. The metallic contact structures on the front and rear sides for making contact with the emitter can preferably be implemented by means of screen printing. The metallic base contact structure can likewise be implemented by means of screen printing. For this purpose, it is possible to employ methods known per se, in particular the so-called LFC method by local melting by means of a laser.

In principle, it should be noted that the solar cell structure according to the invention and the method according to the invention are distinguished in particular by the fact that there are no or only slight restrictions with regard to the choice of the methods for forming the metallic contact structures, such that the customary known methods can be employed and used depending on the configuration of the process line.

Preferably, after the metallic contact structures have been applied, contact firing is carried out insofar as this is necessary for the metallizations. It likewise lies within the scope of the invention for a plurality of contact firing steps to be interposed.

It may likewise be advantageous to carry out further thermal steps for annealing the local contacts and/or for improving the passivation effect (a heat treatment step) in a manner known per se.

### BRIEF DESCRIPTION OF THE DRAWINGS

Further preferred features and embodiments of the solar cell according to the invention and of the method according to the invention are explained below with reference to the figures and the description of the figures, in which:

FIG. 1 shows a schematic illustration of a partial excerpt from an exemplary embodiment of a solar cell according to the invention, and

FIG. 2 shows a comparison of the characteristic curves of three MWT solar cells in the case of reverse loading.

### DETAILED DESCRIPTION OF THE PREFERRED EMBODIMENTS

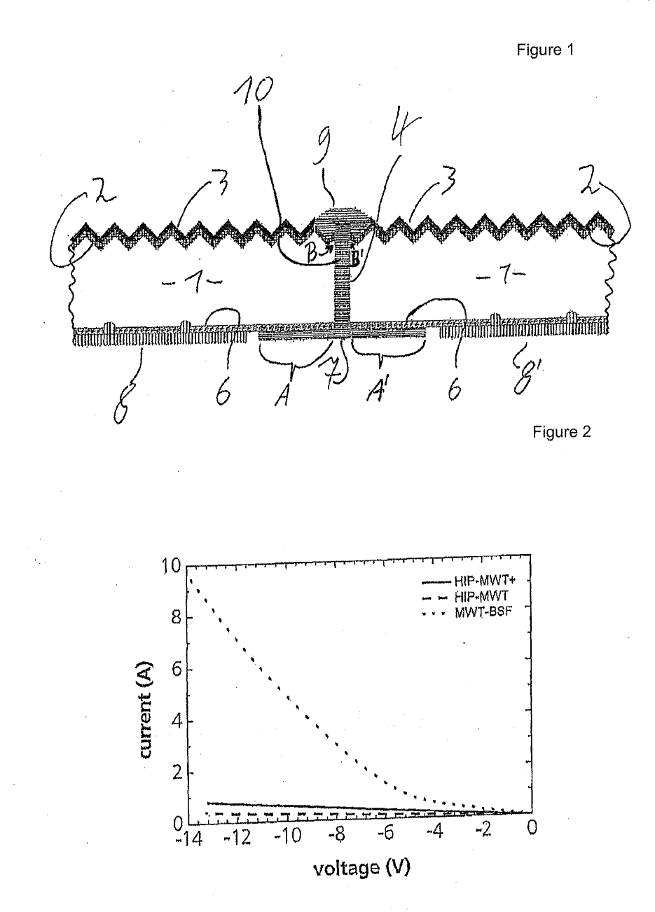

The solar cell according to the invention in FIG. 1 comprises a p-doped semiconductor substrate 1 embodied as a mono- or multi-crystalline silicon wafer having a base resistance of 0.1 ohm cm to 10 ohm cm. A front-side emitter region 2 is formed at the front side, illustrated at the top in FIG. 1. The front side has a texturing in order to increase the coupling in of light and an antireflection layer 3 embodied as a silicon nitride layer and having a thickness of approximately 70 nm is additionally arranged on the front side of the semiconductor substrate 1 in order to increase the coupling in of light.

FIG. 1 merely shows a partial excerpt from the solar cell according to the invention with just one cutout 4. The solar cell continues in a mirror-inverted fashion toward the right and left and has a multiplicity of cutouts, as known per se in the case of MWT solar cell structures.

The cutout 4 extends from the front side to the rear side of the solar cell and is embodied approximately in a cylindrical fashion.

The rear side of the semiconductor substrate 1 is covered by an insulation layer 6 formed by a layer system composed of aluminum oxide and silicon nitride having a total thickness of 100 nm, which insulation layer thus additionally serves as a passivation layer for reducing the surface recombination rate. The insulation layer 6 covers the rear side of the semiconductor substrate 1 over the whole area and is in turn covered both by a metallic rear-side contact structure 7 and by a plurality of metallic base contact structures 8, 8′. The base contact structures 8, 8′ penetrate through the insulation layer 6 at a multiplicity of point-like contact-making regions, such that there is an electrical contact between the base contact structures 8, 8′ and the semiconductor substrate.

A metallic front-side contact structure 9 is formed at the front side of the solar cell, said contact structure being electrically conductively connected to the emitter region 2. In this case, the front-side contact structure 9 is arranged on the semiconductor substrate 1 directly, i.e. without an interposed antireflection layer 3.

A metallic feedthrough structure 10 is formed in the cutout 4. In this exemplary embodiment, front-side contact structure 9, feedthrough structure 10 and rear-side contact structure 7 are formed integrally and correspondingly electrically conductively connected to one another.

It is essential that, firstly, in the overlap regions identified by A and A′ in FIG. 1, although the rear-side contact structure 7 covers the semiconductor substrate 1 in the region of the base doping, it is electrically insulated therefrom by the intervening insulation layer 6. Furthermore, no emitter is formed on the walls of the cutout 4 and at the rear side of the semiconductor substrate 1 and in particular in the regions A and A′. The emitter penetrates into the semiconductor substrate a few μm on the walls of the cutout 4 only in the region identified by B and B′ in FIG. 1, in which region the emitter region 2 adjoins the cutout 4 at the front side.

The semiconductor substrate has a total thickness in the range of 30 μm to 300 μm, of approximately 200 μm in the present case.

The front-side contact structure is embodied as in previously known MWT solar cells, presented for example in “Processing and comprehensive characterization of screen-printed mc-si metal wrap through (mwt) solar cells”, Clement et al., Proceedings of the 22nd European Photovoltaic Solar Energy Conference, Milan, 2007.

The local electrically conductive connections (LFC), produced by means of local heating by a laser, between semiconductor substrate 1 and base contact structure 8, 8′ are distributed approximately uniformly over the base contact structure and embodied approximately in a punctiform fashion with a spacing in the range of 100 μm to 1 mm, in this case of approximately 500 μm. Overall, approximately 98.5% of the rear side of the semiconductor substrate is covered by the insulation layer, and approximately 1.5% by the electrically conductive point contacts. The solar cell has cutouts having a diameter of approximately 100 μm, wherein the cutouts are arranged on lines; on average, one hole is formed per 4 cm² solar cell area.

The exemplary embodiment illustrated in FIG. 1 is produced by the exemplary embodiment of a method according to the invention as described below:

The semiconductor substrate 1 is subjected to surface processing in a method step 0.

In this case, the following method steps are performed: removing surface damage originating from the production of the semiconductor substrate, and forming a texturing at least on the front side in order to improve the light trapping.

Afterward, in a method step C, the insulation layer 6 described above is applied over the whole area on the rear side of the semiconductor substrate. As an alternative to the insulation layer 6 described above, the insulation layer can also be formed as a silicon oxide layer having a thickness of 200 nm and can be produced for example by means of PECVD or thermal oxidation with subsequent etching-back on one side.

Afterward, cleaning can be carried out, wherein the semiconductor substrate is freed of possible contaminants and residues. This cleaning is preferably carried out wet-chemically using caustic liquids such as hydrofluoric acid, potassium hydroxide solution or other substances.

A method step B subsequently involves producing the above-described emitter region 2 at the front side of the semiconductor substrate 1. For this purpose, a diffusion from the gas phase is carried out, such that phosphorus-containing glass is deposited on the semiconductor substrate and is subsequently applied into the semiconductor substrate by the action of temperature on the front side. On the rear side, the insulation layer already applied acts as a diffusion barrier, with the result that no emitter is formed on the rear side. The diffusion of the emitter is carried out by heating the semiconductor substrate to a temperature in the range of 800° C. to 900° C. for a time duration of approximately 45 min.

The silicate glass that arises in this case is subsequently removed in an etching step by means of dipping the semiconductor substrate into hydrofluoric acid having a concentration of approximately 10% for a time duration of approximately 30 s.

Afterward, the antireflection layer 3 is applied to the front side of the semiconductor substrate in order to improve the coupling in of light, wherein the antireflection layer 3 is embodied as a silicon nitride layer having a thickness of approximately 70 nm. The antireflection layer 3 can likewise be formed as a layer system, in particular comprising one or more of the layers silicon oxide, aluminum oxide, silicon nitride.

A method step A subsequently involves producing a plurality of cutouts, the so-called “MWT holes”, having a diameter of preferably 50 μm to 200 μm. The MWT holes are produced by means of a laser, as described for example in “Emitter wrap-through solar cell”, Gee et al., Proceedings of the 23rd IEEE Photovoltaic Specialists Conference, Louisville, 1993. In the process, the holes are formed at those positions of the semiconductor substrate at which the rear-side contact structure is arranged in the subsequent method steps.

Since the cutouts are only produced after the emitter has been formed, the walls of the cutouts do not have to be post-processed in a complex method step, since no emitter is formed on the walls of the cutouts and, consequently, there is no risk of significant impairment of the efficiency as a result of a leakage current in the space charge zone of an emitter on the walls of the cutouts.

A method step D subsequently involves forming the metallic contact structures: feedthrough contact structure, rear-side contact structure, base contact structure, and front-side contact structure. This can be carried out by means of screen printing for example in a manner known per se.

In FIG. 2 there are measured characteristic curves of three MWT solar cell structures:

The solid characteristic curve identified by “HIP-MWT+” was measured on a solar cell corresponding to the exemplary embodiment of a solar cell according to the invention as illustrated in FIG. 1. The dashed characteristic curve illustrated and identified by “HIP-MWT” corresponds to a solar cell in accordance with DE 10 2010 026 960 A1, which therefore likewise has an insulation layer at the rear side, but furthermore an emitter region on the walls of the cutout. The dotted characteristic curve illustrated and identified by “MWT-BSF” corresponds to a solar cell in accordance with FIG. 4 of WO 2012/026812, which therefore has no emitter on the walls of the cutout and no electrical insulation layer on the rear side of the semiconductor substrate.

The measurement was carried out in each case under reverse loading. The illustration shows the respectively applied voltage in V against the measured current in A. It can clearly be discerned that the solar cell according to the invention HIP-MWT+ has only a slightly higher current under reverse loading compared with the HIP-MWT (dashed line), which can be regarded as a reference here. In both cases, the current flow under reverse loading is sufficiently low such that the risk of evolution of heat that damages the solar cell or the module in the case of partial shading is low. The characteristic curve of the MWT-BSF solar cell (dotted) has considerably higher currents, however. Here there is a considerable risk of the solar cell and/or the module being damaged due to evolution of heat in the case of partial shading, with the result that it is necessary to provide additional bypass diodes in a module.

1. A photovoltaic solar cell having a front side designed for coupling in light, the solar cell comprises
a semiconductor substrate (1) of a base doping type,
at least one emitter region (2) of an emitter doping type formed at the front side, said emitter doping type being opposite to the base doping type,
at least one metallic front-side contact structure (9) formed on the front side for collecting current and electrically conductively connected to the emitter region (2),
at least one metallic base contact structure (8, 8′) arranged at a rear side of the solar cell and electrically conductively connected to the semiconductor substrate (1) in a region of the base doping type,
at least one cutout (4) extending from the front side to the rear side in the semiconductor substrate (1) and at least one feedthrough structure (10), the feedthrough structure (10) is guided in the cutout (4) from the front side to the rear side of the semiconductor substrate and is electrically conductively connected to the front-side contact structure (9), and
at least one metallic rear-side contact structure (7) arranged at the rear side and electrically conductively connected to the feedthrough structure (10), an electrically insulating insulation layer (6) arranged on the rear side of the semiconductor substrate or on further intermediate layers, and covers the rear side at least in regions surrounding the cutout (4),
the rear-side contact structure (7) is arranged on the insulation layer (6) or on the further intermediate layers, such that the rear-side contact structure (7) is electrically insulated by the insulation layer (6) from the semiconductor substrate (1) lying below the insulation layer (6), and in the semiconductor substrate (1) on the walls of the cutout (4) away from the front-side emitter region, the feedthrough structure (10) directly adjoins a base region of the base doping type.

2. The photovoltaic solar cell as claimed in claim 1, wherein no emitter is formed at the rear side of the solar cell.

3. The photovoltaic solar cell as claimed in claim 1, wherein the metallic rear-side contact structure (7) covers at least 0.05% and at most 5% of the insulation layer.

4. The photovoltaic solar cell as claimed in claim 1, wherein the feedthrough structure is formed as a metal pin or by a conductive adhesive.

5. The photovoltaic solar cell as claimed in claim 1, wherein the specific conductivity of the feedthrough structure is substantially constant at least in a horizontal direction.

6. A method for producing a photovoltaic solar cell having a front side designed for coupling in light, comprising the following method steps:
(A) producing a plurality of cutouts in a semiconductor substrate (1) of a base doping type,
(B) producing one or more emitter regions of an emitter doping type at least at the front side of the semiconductor substrate, wherein the emitter doping type is opposite to the base doping type,
(C) applying an electrically insulating insulation layer (6), and
(D) producing feedthrough structures in the cutouts, including
forming at least one metallic base contact structure (8, 8′) at the rear side of the solar cell in an electrically conductive manner with the semiconductor substrate (1) in a base doping region,
forming at least one metallic front-side contact structure (9) at the front side of the solar cell in an electrically conductive manner with the emitter region (2) at the front side of the semiconductor substrate in a manner electrically conductively connected to the feedthrough structure, and
forming at least one rear-side contact structure (7) at the rear side of the solar cell in a manner electrically conductively connected to the feedthrough structure,
wherein in method step C the insulation layer (6) is applied in a manner covering the rear side of the semiconductor substrate, indirectly or directly,
in method step D,
the rear-side contact structure (7) is applied to the insulation layer (6), indirectly or directly, in such a way that the rear-side contact structure (7) extends over regions of the semiconductor substrate having base doping and, in said regions, at least due to the intervening insulation layer (6), an electrical insulation is formed between rear-side contact structure (7) and the semiconductor substrate (1), and
the base contact structure (8, 8′) is applied to the insulation layer (6) or further intermediate layers in such a way that the base contact structure (8, 8′) penetrates through the insulation layer (6) at least in regions, such that an electrically conductive connection is produced between base contact structure (8, 8′) and semiconductor substrate (1), and
in the semiconductor substrate (1) on the walls of the cutout (4), the feedthrough structure (10) away from the front-side emitter region is formed in a manner directly adjoining a base region of the base doping type.

7. The method as claimed in claim 6, wherein in that method step A is performed after method step B.

8. The method as claimed in claim 6, wherein the feedthrough structure (10) is formed in a manner directly adjoining one or a plurality of the base regions of the base doping type.

9. The method as claimed in claim 6, wherein no emitter region (2) extending parallel to the rear side is formed in a manner adjoining the cutouts at the rear side of the semiconductor substrate.

10. The method as claimed in claim 6, wherein in method step A the cutouts are formed by a laser.

11. The method as claimed in claim 6, wherein method step A is performed before method step B and before method step C, such that in method step B an emitter is also formed at least slightly on the walls of the cutouts produced in method step A, and also on the rear side of the semiconductor substrate, and in a method step X after method step B the emitter is removed again on the walls of the cutouts and, also at the rear side of the semiconductor substrate a wet-chemical or plasma-based emitter back-etch.

12. The method as claimed in claim 6, wherein method step B is carried out after method step C.

13. The method as claimed in claim 6, wherein in a method step T at least the front side of the semiconductor substrate is textured.

14. The method as claimed in claim 13, wherein a multiplicity of precursors are provided by method steps B, C, and T being performed on a multiplicity of the semiconductor substrates, and the precursors are used without the formation of cutouts for production of a conventional solar cell contacted on both sides or, by method steps A and D being carried out, for the formation of an MWT solar cell.

15. The method as claimed in claim 6, wherein in method step D the feedthrough structures are formed by a non-contacting metal paste, by metal pins, or by conductive adhesive.
